(19) United States
(12) Patent Application Publication
(10) Pub. No.: US 2025/0269462 A1
(43) Pub. Date: Aug. 28, 2025

(54) LASER PROCESSING METHOD, LASER PROCESSING APPARATUS, AND ELECTRONIC DEVICE MANUFACTURING METHOD

(71) Applicant: Gigaphoton Inc., Tochigi (JP)

(72) Inventor: Akira SUWA, Oyama-shi (JP)

(73) Assignee: Gigaphoton Inc., Tochigi (JP)

(21) Appl. No.: 19/010,670

(22) Filed: Jan. 6, 2025

(30) Foreign Application Priority Data
Feb. 22, 2024 (JP) 2024-025561

(51) Int. Cl. B23K 26/066; B23K 26/40; B23K 101/40

(52) U.S. Cl. CPC B23K 26/066; B23K 26/40; B23K 2101/40

(57) ABSTRACT

A laser processing method for irradiating a workpiece with laser light output by a laser apparatus via a mask, the irradiation via the mask including irradiating the workpiece with the laser light via a first mask pattern in which a first via pattern and a first trench pattern including a first pad section are formed, and irradiating the workpiece with the laser light via a second mask pattern in which a second trench pattern and a second via pattern are formed, irradiating the workpiece with the laser light via the second mask pattern including positioning a second processed trench section processed via the second trench pattern so as to be adjacent to a first processed trench section of the workpiece processed via the first trench pattern, and positioning a second processed via section processed via the second via pattern so as to be inside a first processed pad section of the workpiece processed via the first pad section.

### CROSS-REFERENCE TO RELATED APPLICATIONS

The present application claims the benefit of Japanese Patent Application No. 2024-025561, filed on Feb. 22, 2024, the entire contents of which are hereby incorporated by reference.

### BACKGROUND

### 1. Technical Field

The present disclosure relates to a laser processing method, a laser processing apparatus, and an electronic device manufacturing method.

### 2. Related Art

Circuit boards, which are widely used in a variety of electronic instruments, are required to have finer, denser circuit wiring as the electronic instruments are miniaturized and equipped with advanced functions. As a circuit board manufacturing technology, there is a known manufacturing method based on a build-up scheme in which an insulating layer and a conductor layer are alternately stacked on an inner layer substrate. In the manufacturing method based on the build-up scheme, the insulating layer is formed by using, for example, an adhesive layer including a support and a resin composition layer provided on the support to stack the resin composition layer on the inner layer substrate, and thermally curing the resin composition layer. The thus formed insulating layer is then irradiated with laser light to form via holes for connecting the conductor layer. A circuit is then formed by performing seed layer formation, lithography, plating, and etching the seed layer.

To achieve higher circuit wiring density, it is desired to reduce the diameter of the via holes and the width of the wiring. Via holes are typically formed by laser drilling, and carbon dioxide gas lasers, which are advantageous in terms of high drilling speed and low manufacturing cost, are currently used as a primary choice. There is, however, a limit to the reduction in the diameter of via holes. For example, it is difficult for a carbon dioxide gas laser to form a via hole having an opening diameter smaller than or equal to 25 μm. Also as for the wiring width, it is difficult for a semiconductor packaging apparatus using lithography and etching to form wiring pattern lines and spaces each having a width of 2 μm or smaller.

For further miniaturization of via holes and reduction in wiring width, use of excimer lasers has been examined as an alternative to carbon dioxide lasers.

The excimer laser light, which has a pulse width of about several tens of nanoseconds and has a short wavelength of, for example, 248.4 nm or 193.4 nm, is used in some cases to directly process a polymer material, a glass material, and other materials.

The excimer laser light having photon energy higher than the binding energy of a polymer material can unbind the molecules that form the polymer material. Non-thermal processing can therefore be performed, and it is known that an excellent processed shape is achieved by the non-thermal processing.

Excimer lasers generally produce intense laser light that belongs to the ultraviolet region and therefore do not generate heat, unlike infrared lasers such as carbon dioxide gas lasers. Finer processing is therefore achievable and is expected to contribute to miniaturization of via holes and reduction in wiring width.

### CITATION LIST

### Patent Literature

[PTL 1] JP-A-2022-164707
[PTL 2] U.S. Pat. No. 6,136,479

### SUMMARY

A laser processing method according to an aspect of the present disclosure is a laser processing method for irradiating a workpiece with laser light output by a laser apparatus via a mask, the workpiece including a substrate and an insulating film formed on the substrate, the irradiation via the mask including irradiating the workpiece with the laser light via a first mask pattern in which a first via pattern and a first trench pattern including a first pad section are formed, and irradiating the workpiece with the laser light via a second mask pattern in which a second trench pattern and a second via pattern are formed, irradiating the workpiece with the laser light via the second mask pattern including positioning a second processed trench section processed via the second trench pattern so as to be adjacent to a first processed trench section of the workpiece processed via the first trench pattern, and positioning a second processed via section processed via the second via pattern so as to be inside a first processed pad section of the workpiece processed via the first pad section.

An electronic device manufacturing method according to another aspect of the present disclosure is an electronic device manufacturing method for manufacturing an electronic device by irradiating a workpiece with laser light output by a laser apparatus via a mask, the workpiece including a substrate and an insulating film formed on the substrate, the irradiation via the mask including irradiating the workpiece with the laser light via a first mask pattern in which a first via pattern and a first trench pattern including a first pad section are formed, and irradiating the workpiece with the laser light via a second mask pattern in which a second trench pattern and a second via pattern are formed, irradiating the workpiece with the laser light via the second mask pattern including positioning a second processed trench section processed via the second trench pattern so as to be adjacent to a first processed trench section of the workpiece processed via the first trench pattern, and positioning a second processed via section processed via the second via pattern so as to be inside a first processed pad section of the workpiece processed via the first pad section.

A laser processing apparatus according to another aspect of the present disclosure is a laser processing apparatus for irradiating a workpiece with laser light output by a laser apparatus via a mask, the laser processing apparatus including: a mask placement member at which a first mask and a second mask are placed; a mask moving mechanism configured to move one of the first mask and the second mask placed at the mask moving member to a position where the laser light is radiated; and a processor, the processor moving the first mask to the position where the laser light is radiated, and irradiating the workpiece with the laser light via a first via pattern and a first trench pattern including a first pad section, the first via pattern and the first trench pattern formed at the first mask, and moving the second mask to the position where the laser light is radiated, and irradiating the workpiece with the laser light via a second trench pattern and a second via pattern formed at the second mask, irradiating the workpiece with the laser light via the second trench pattern and the second via pattern including positioning a second processed trench section processed via the second trench pattern so as to be adjacent to a first processed trench section of the workpiece processed via the first trench pattern, and positioning a second processed via section processed via the second via pattern so as to be inside a first processed pad section of the workpiece processed via the first pad section.

### BRIEF DESCRIPTION OF DRAWINGS

Embodiments of the present disclosure will be described below only by way of example with reference to the accompanying drawings.

FIG. 1 shows the configuration of a laser processing system using mask transfer according to Comparative Example.

FIG. 2 is a plan view showing an example of a radiation beam with which a mask is illuminated.

FIG. 3 shows a build-up substrate that is an example of a workpiece.

FIG. 4 shows processing using multiple masks according to Comparative Example.

FIG. 5 is a flowchart showing steps of a processing method using a trench mask and a via mask.

FIG. 6 shows shoulder slopes.

FIG. 7 shows processing using multiple masks according to a first embodiment.

FIG. 8 is a flowchart showing steps of a processing method according to the first embodiment.

FIG. 9 is a flowchart showing steps of a processing method according to a variation of the first embodiment.

FIG. 10 shows a processing method according to a second embodiment.

FIG. 11 shows the configuration of a laser processing system according to a third embodiment.

FIG. 12 is a plan view of a mask movement mechanism.

### DETAILED DESCRIPTION

### Contents

1. Description of terms
2. Overview of laser processing system using mask transfer according to Comparative Example
2.1 Configuration
2.2 Operation
2.3 Problems
3. First Embodiment
3.1 Configuration
3.2 Operation
3.3 Effects and advantages
3.4 Variation
3.4.1 Configuration and operation
3.4.2 Effects and advantages
4. Second Embodiment
4.1 Configuration
4.2 Operation
4.3 Effects and advantages
5. Third Embodiment
5.1 Configuration
5.2 Operation
5.3 Effects and advantages
6. Electronic devices manufacturing method
7. Others

Embodiments of the present disclosure will be described below in detail with reference to the drawings. The embodiments described below show some examples of the present disclosure and are not intended to limit the contents of the present disclosure. Furthermore, all configurations and operations described in the embodiments are not necessarily essential as configurations and operations in the present disclosure. The same elements have the same reference characters, and no redundant description of the same elements will be made.

### 1. Description of Terms

The term “via” is a through hole that passes through at least one layer of a multi-layer substrate.

The term “pad” is a portion formed around a via and having a dimension greater than the diameter of the via so that a lead of an electronic component can be soldered to the portion, plus a portion located below the via and having a dimension greater than the diameter of the via.

### 2. Overview of Laser Processing System Using Mask Transfer According to Comparative Example

### 2.1 Configuration

A laser processing system using mask transfer according to Comparative Example will be described. Comparative Example in the present disclosure is a form that the applicant is aware of as known only by the applicant, and is not a publicly known example that the applicant is self-aware of.

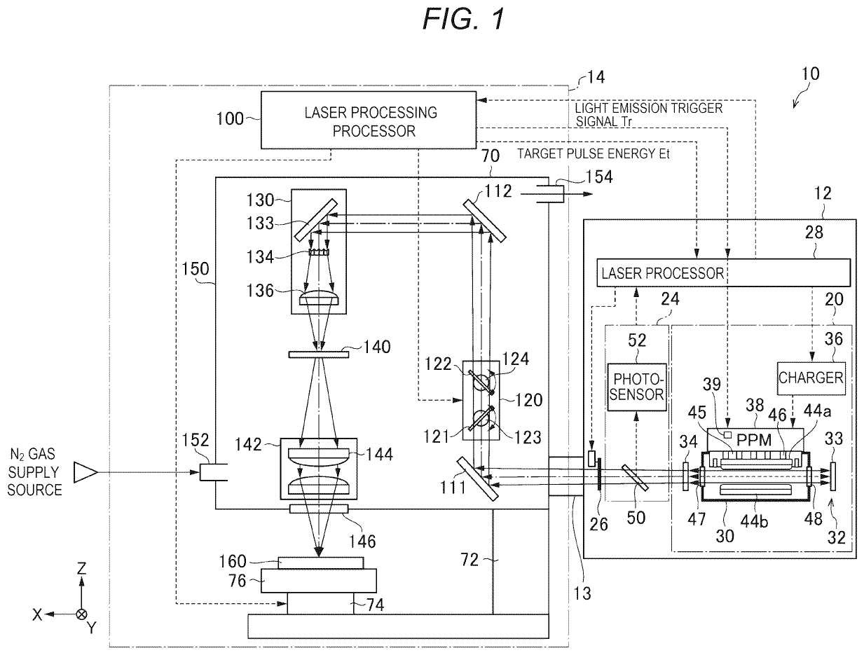

FIG. 1 shows the configuration of a laser processing system 10 using mask transfer according to Comparative Example. The laser processing system 10 includes a laser apparatus 12, an optical path tube 13, and a laser processing apparatus 14. The optical path tube 13 is disposed in the optical path of laser light between a light exiting port of the laser apparatus 12 and a light incident port of the laser processing apparatus 14.

The laser apparatus 12 is an excimer laser apparatus that outputs ultraviolet pulse laser light. For example, the laser apparatus 12 may be a discharge-excitation-type laser apparatus using a laser medium made of F₂, ArF, KrF, XeCl, or XeF. The laser apparatus 12 includes a master oscillator (MO) 20, a monitor module 24, a shutter 26, and a laser processor 28.

The master oscillator 20 includes a chamber 30, an optical resonator 32, a charger 36, and a pulse power module (PPM) 38.

The chamber 30 encapsulates an excimer laser gas containing the laser medium. The excimer laser gas may be a mixture gas containing a rare gas, such as Ar, Kr, or Xe, a halogen gas, such as F₂ or Cl₂, and a buffer gas, such as He or Ne.

The chamber 30 includes a pair of electrodes 44a and 44b and windows 47 and 48. The pair of electrodes 44a and 44b are disposed in the chamber 30. The electrode 44a is supported by an insulating member 45. The electrode 44a is connected to the PPM 38 via conductive sections 46 embedded in feedthrough portions of the insulating member 45. The electrode 44b is supported by a return plate that is not shown, and the return plate is connected to the inner surface of the chamber 30 via wiring that is not shown.

The PPM 38 includes a switch 39, a step-up transformer, and a magnetism compression circuit, neither of the latter two components is shown. The PPM 38 is connected to the charger 36. The charger 36 is a DC power supply apparatus that charges a charging capacitor that is not shown in the PPM 38 with a predetermined voltage.

The optical resonator 32 includes a rear mirror 33 and an output coupling mirror 34. The rear mirror 33 includes a planar substrate coated with a highly reflective film. The output coupling mirror 34 includes a planar substrate coated with a partially reflective film. The chamber 30 is disposed in the optical path of the optical resonator 32.

The monitor module 24 includes a beam splitter 50 and a photosensor 52.

The shutter 26 is disposed in the optical path of the pulse laser light output from the monitor module 24.

The optical path of the pulse laser light may be encapsulated by an enclosure that is not shown and the optical path tube 13 and purged, for example, with an N₂ gas.

The laser processing apparatus 14 includes a radiation optical system 70, a frame 72, an XYZ stage 74, a table 76, and a laser processing processor 100. A workpiece 160 is fixed onto the table 76.

The radiation optical system 70 includes highly reflective mirrors 111 to 112, an attenuator 120, an illumination optical system 130, a mask 140, a projection optical system 142, a window 146, and an enclosure 150.

The highly reflective mirror 111 is so disposed that the laser light having passed through the optical path tube 13 passes through the attenuator 120 and is incident on the highly reflective mirror 112.

The attenuator 120 is disposed in the optical path between the highly reflective mirror 111 and the highly reflective mirror 112. The attenuator 120 includes two partially reflective mirrors 121 and 122 and rotary stages 123 and 124 capable of changing the angles of incidence of the light incident on the partially reflective mirrors 121 and 122.

The highly reflective mirror 112 is so disposed that the laser light having passed through the attenuator 120 enters the illumination optical system 130.

The illumination optical system 130 includes a highly reflective mirror 133, a fly-eye lens 134, and a condenser lens 136. The illumination optical system 130 is disposed so as to illuminate the mask 140 with a rectangular radiation beam in the form of Koehler illumination.

The highly reflective mirror 133 is so disposed that the pulse laser light incident thereon enters the fly-eye lens 134.

The fly-eye lens 134 is, for example, so disposed that the focal plane of the fly-eye lens 134 coincides with the front focal plane of the condenser lens 136. The condenser lens 136 is, for example, so disposed that the back focal plane of the condenser lens 136 coincides with the position of the mask 140. The illumination optical system 130 is so disposed that the mask 140 is uniformly illuminated with the laser light.

The mask 140 is, for example, a mask including a synthetic quartz substrate which transmits ultraviolet light and on which a patterned metal or dielectric multilayer film is formed. For example, to process via holes in the workpiece 160, which is a printed board, patterns used to form holes each having a diameter ranging from 5 μm to 30 μm are formed at the mask 140. When the projection optical system 142 magnifies the dimensions of the patterns of the mask 140 by a factor of M to processed dimensions, the patterns formed at the mask 140 have dimensions 1/M times the processed dimensions.

The projection optical system 142 is disposed so as to form an image of the mask 140 at the surface of the workpiece 160 via the window 146. The projection optical system 142 may be a reduction projection optical system that is the combination of multiple lenses 144.

The window 146 is disposed in the optical path between the projection optical system 142 and the workpiece 160. The window 146 is disposed in a hole provided in the enclosure 150, for example, via an O ring that is not shown. The window 146 may be a substrate made of CaF₂ crystal or synthetic quartz substrate, which transmits the excimer laser light, and may be coated with reflection suppression films on both sides.

The enclosure 150 has an inlet 152 and an outlet 154, via which a nitrogen (N₂) gas enters and exits out of the enclosure 150. The enclosure 150 may be sealed, for example, with O rings that are not shown so that outside air does not enter the enclosure 150. The N₂-gas inlet 152 is connected to an N₂ gas supply source.

The radiation optical system 70 and the XYZ stage 74 are fixed to the frame 72. The XYZ stage 74 is a motorized stage that moves the position where the workpiece 160 is irradiated with the pulse laser light relative to the workpiece 160. The table 76 is fixed onto the XYZ stage 74. The workpiece 160 is fixed onto the table 76.

The workpiece 160 may, for example, be an interposer substrate that functions as a relay between an LSI chip and a main printed board or a flexible printed board. An electrically insulating film on the substrate is made of an material, for example, a polymer material, a glass epoxy material, and a glass material.

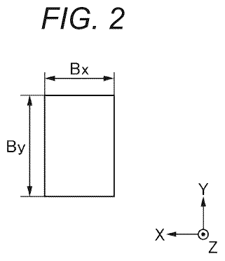

FIG. 2 is a plan view showing an example of a radiation beam with which the mask 140 is illuminated. Let Bx be the width of the radiation beam in the X direction, and By be the width of the radiation beam in the Y direction, as shown in FIG. 2. In the example shown in FIG. 2, the rectangular radiation beam satisfies Bx<By.

### 2.2 Operation

A user places an appropriate mask 140 in the laser processing apparatus 14 in advance.

The laser processing processor 100 reads radiation condition parameters used when the laser processing is performed. Specifically, the laser processing processor 100 reads a fluence, a radiated pulse count, and a repetition frequency at the workpiece 160 during the laser processing. The radiation condition may include at least one of the fluence, the radiated pulse count, and the repetition frequency.

The laser processing processor 100 causes the laser apparatus 12 to perform tuning oscillation. To this end, the laser processing processor 100 transmits target pulse energy Et to the laser processor 28.

Upon reception of the target pulse energy Et, the laser processor 28 closes the shutter 26 and controls the charger 36 in such a way that the target pulse energy Et is produced. The laser processor 28 causes an internal trigger generator that is not shown to generate an internal trigger signal. The generated internal trigger signal is input to the switch 39 of the PPM 38, resulting in spontaneous oscillation of the master oscillator 20.

The pulse laser light output from the master oscillator 20 is sampled by the beam splitter 50 of the monitor module 24, and pulse energy E is measured.

The laser processor 28 controls the charging voltage from the charger 36 in such a way that a difference ΔE between the pulse energy E and the target pulse energy Et approaches zero.

The laser processor 28 transmits an external trigger OK signal to the laser processing processor 100 to open the shutter 26 when ΔE falls within an allowable range.

The laser processing processor 100 receives the external trigger OK signal from the laser processor 28.

The laser processing processor 100 then controls the X-axis and Y-axis of the XYZ stage 74 in such a way that an irradiated region to which the projection optical system 142 transfers the image of the mask 140 is located at an appropriate position on the workpiece 160.

The laser processing processor 100 further controls the Z-axis of the XYZ stage 74 in such a way that the image of the mask 140 is formed at the position of the surface of the workpiece 160.

The laser processing processor 100 causes the rotary stages 123 and 124 to control the angles of incidence of the pulse laser light incident on the two partially reflective mirrors 121 and 122 in such a way that the fluence of the pulse laser light at the position of the surface of the workpiece 160 (position of image of mask 140) is a target fluence.

The laser processing processor 100 transmits a light emission trigger signal Tr having a predetermined repetition frequency to the laser processor 28. As a result, the pulse laser light is output from the master oscillator 20 in synchronization with the light emission trigger signal Tr. The pulse laser light having passed through the beam splitter 50 of the monitor module 24 enters the laser processing apparatus 14 via the optical path tube 13.

The pulse laser light having entered the laser processing apparatus 14 is reflected off the highly reflective mirror 111, and passes through the attenuator 120, which attenuates the pulse laser light, and the attenuated pulse laser light is reflected off the highly reflective mirror 112.

The pulse laser light reflected off the highly reflective mirror 112 at high reflectance is reflected off the highly reflective mirror 133 of the illumination optical system 130, spatially homogenized in terms of light intensity by the fly-eye lens 134, and incident as the radiation beam on the mask 140.

The pulse laser light having passed through the mask 140 enters the projection optical system 142. The pulse laser light having passed through the projection optical system 142 undergoes reduction projection (transferred image formation) and is radiated to the surface of the workpiece 160. As a result, the portion irradiated with the pulse laser light out of the surface of the workpiece 160 undergoes the laser processing.

### 2.3 Problems

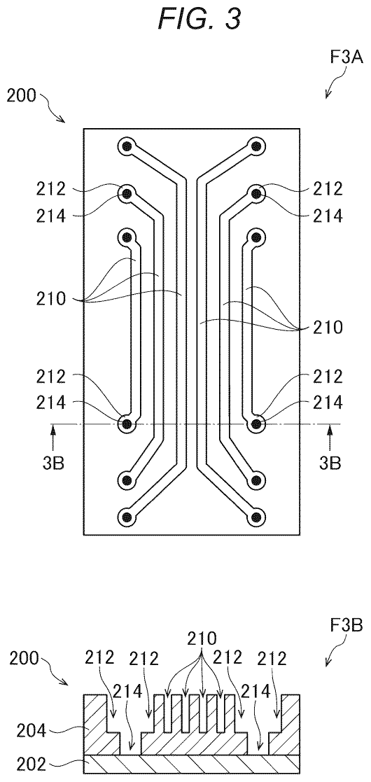

FIG. 3 shows a build-up substrate 200, which is an example of the workpiece 160. F3A in FIG. 3 is a plan view of the processed build-up substrate 200. F3B in FIG. 3 is a cross-sectional view taken along the line 3B-3B in F3A.

The build-up substrate 200 includes a substrate 202 and an insulating film 204 made, for example, of a polymer material and layered at the upper surface of the substrate 202. The build-up substrate 200 further has trenches 210, pads 212, and vias 214 processed in the insulating film 204.

The vias 214 pass through the insulating film 204. The trenches 210 and the pads 212 are each a recess formed by removal of a portion of the insulating film 204. The pads 212 are formed around the vias 214. The trenches 210 each cause two pads 212 to communicate with each other. Note in F3B that the lateral positions of the trenches 210, the pads 212, and the vias 214 have been changed as appropriate to facilitate understanding.

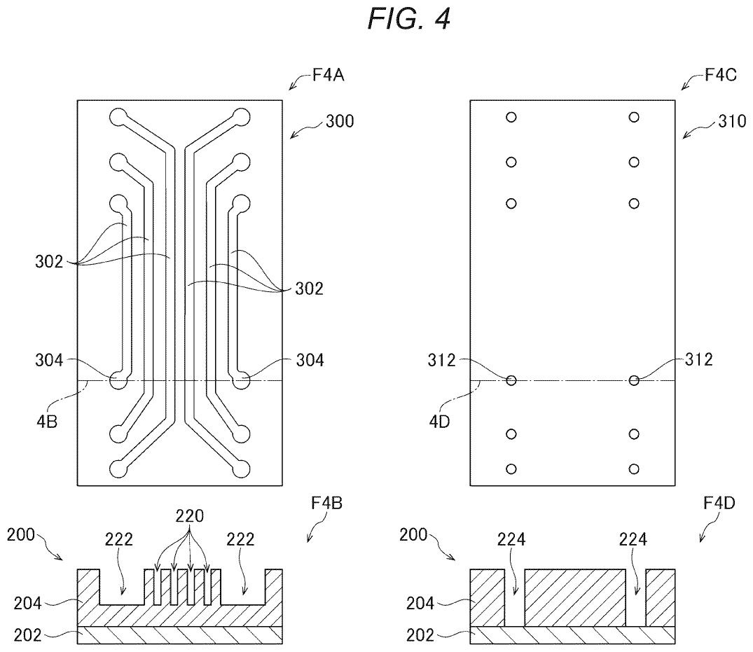

To process the build-up substrate 200 shown in FIG. 3, the processing is performed in multiple steps using multiple masks in some cases. FIG. 4 shows processing using multiple masks according to Comparative Example.

F4A is a top view of a trench mask 300. The trench mask 300 has trench patterns 302 and pad patterns 304, which are laser light transmitting regions corresponding to the trenches 210 and the pads 212, respectively, to be processed in the insulating film 204 of the build-up substrate 200.

F4B shows the build-up substrate 200 processed by using the trench mask 300, and is a cross-sectional view taken along the line 4B in F4A. Processed trench sections 220 and processed pad sections 222 are formed in the insulating film 204 of the build-up substrate 200, as shown in F4B, the processed trench sections 220 being sections processed by the pulse laser light having passed through the trench patterns 302, and the processed pad sections 222 being sections processed by the pulse laser light having passed through the pad patterns 304. The processed trench sections 220 and the processed pad sections 222 are each a recess formed by removal of the insulating film 204 halfway in the thickness direction.

F4C is a top view of a via mask 310. The via mask 310 has via patterns 312, which are laser light transmitting regions corresponding to the vias 214 to be processed in the insulating film 204 of the build-up substrate 200.

F4D shows the build-up substrate 200 processed by using the via mask 310, and is a cross-sectional view taken along the line 4D in F4C. Processed via sections 224 processed by the pulse laser light having passed through the via patterns 312 are formed in the insulating film 204 of the build-up substrate 200, as shown in F4D. The processed via sections 224 are through holes passing through the insulating film 204.

The processing using the trench mask 300 and the following processing with the mask switched to the via mask 310 can produce the build-up substrate 200 shown in FIG. 3. In this case, it is necessary that the processed trench sections 220 and the processed pad sections 222 do not pass through the insulating film 204 but a portion thereof is left. To this end, the number of times of laser light radiation or the fluence may be adjusted. On the other hand, since the processed via sections 224 need to pass through the insulating film 204, the laser light radiation condition may differ from that under which the trench mask 300 is used.

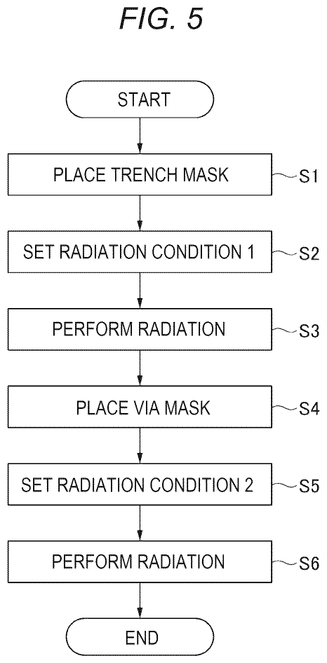

FIG. 5 is a flowchart showing steps of a processing method using the trench mask 300 and the via mask 310.

In step S1, the user places the trench mask 300 in the laser processing apparatus 14. In step S2, the laser processing processor 100 sets the radiation condition to a radiation condition 1. In step S3, the laser processing apparatus 14 irradiates the surface of the build-up substrate 200 with the pulse laser light via the trench mask 300 to perform the processing.

The trenches 210 and the pads 212 are thus formed in the insulating film 204.

In step S4, the user places the via mask 310 in the laser processing apparatus 14. In step S5, the laser processing processor 100 sets the radiation condition to a radiation condition 2. In step S6, the laser processing apparatus 14 irradiates the surface of the build-up substrate 200 with the pulse laser light via the via mask 310 to perform the processing.

The vias 214 are thus formed in the insulating film 204. The processes in the flowchart are thus completed.

In such processing of the build-up substrate 200, the need for miniaturization thereof has increased in recent years, so that what is called shoulder slopes may occur, that is, for example, inclining end portions are left at both sides of the each of the trenches 210 of the insulating film 204, where right-angled end portions should originally be formed.

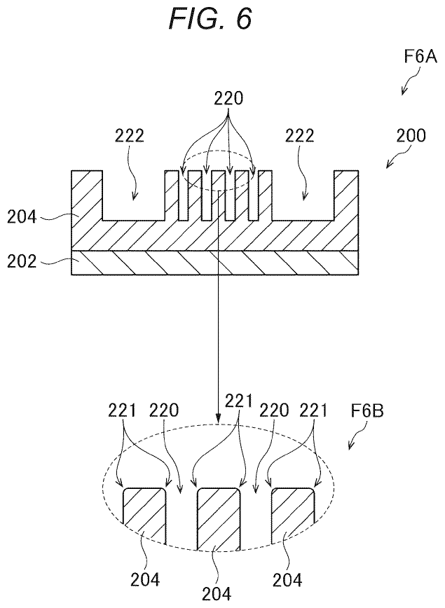

FIG. 6 shows shoulder slopes. F6A in FIG. 6 is the same as F4B in FIG. 4, and shows the build-up substrate 200 having the processed trench sections 220 processed by using the trench mask 300. F6B in FIG. 6 is an enlarged view of a portion of F6A, and shows an upper portion of the processed trench sections 220. In the example shown in F6B, shoulder slopes 221 occur in the insulating film 204 at both sides of each of the processed trench sections 220.

Such shoulder slopes occur when the distance between adjacent linear portions to be processed is close and the resolution limit makes the light shielding by the mask (corresponding to portions to be left) insufficient. To suppress the shoulder slopes, it is conceivable to perform double patterning only for the trench patterns, resulting, however, in a drawback of an increase in the number of masks.

A finer pattern processing method that suppresses shoulder slopes while minimizing the increase in the number of masks has therefore been required.

### 3. First Embodiment

### 3.1 Configuration

The configuration of a laser processing system according to a first embodiment is the same as that of the laser processing system 10 according to Comparative Example. In the first embodiment, instead of the processing using only trench patterns and the processing using only via patterns are separately performed, laser processing is performed by using multiple masks having trench patterns and via patterns mixed with each other.

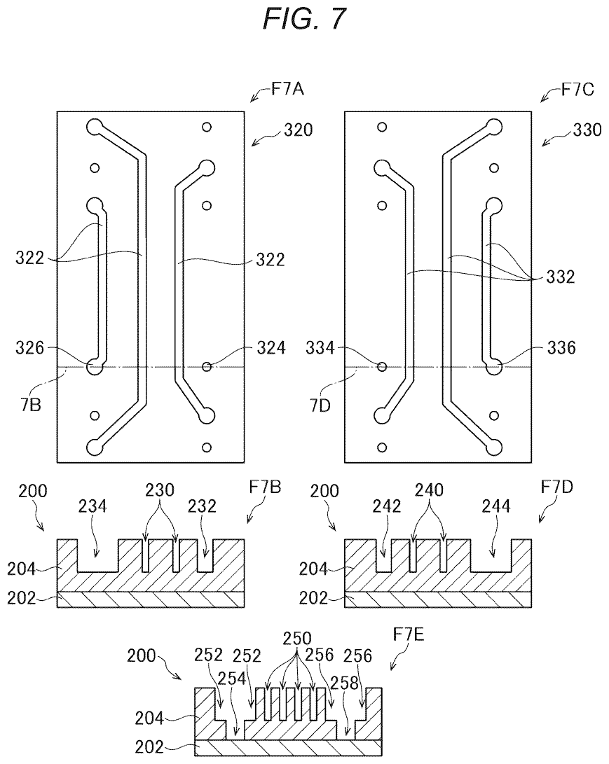

FIG. 7 shows processing using multiple masks according to a first embodiment. F7A is a top view of a first mask 320. The first mask 320 has first trench patterns 322 and first via patterns 324, which are laser light transmitting regions, mixed with each other. The first trench patterns 322 and the first via patterns 324 are each an example of the “first mask pattern” in the present disclosure. The first trench patterns 322 each include first pad sections 326 used to form pads to be connected to the trench.

F7B shows the build-up substrate 200 processed by using the first mask 320, and is a cross-sectional view taken along the line 7B in F7A. First processed trench sections 230, first processed via sections 232, and first processed pad sections 234 are formed in the insulating film 204 of the build-up substrate 200, as shown in F7B, the first processed trench sections 230 being sections processed by the pulse laser light having passed through the first trench patterns 322, the first processed via sections 232 being sections processed by the pulse laser light having passed through the first via patterns 324, and the first processed pad sections 234 being sections processed by the pulse laser light having passed through the first pad sections 326 of the first trench patterns 322. The first processed trench sections 230, the first processed via sections 232, and the first processed pad sections 234 are each a recess formed by removal of the insulating film 204 halfway in the thickness direction.

The portion labeled with F7C is a top view of a second mask 330. The second mask 330 includes second trench patterns 332 and second via patterns 334, which are laser light transmitting regions, mixed with each other. The second trench patterns 332 and the second via patterns 334 are each an example of the “second mask pattern” in the present disclosure. The second trench patterns 332 each include second pad sections 336 used to form pads to be connected to the trench.

The portion labeled with F7D shows the build-up substrate 200 processed by using the second mask 330, and is a cross-sectional view taken along the line 7D in F7C. Second processed trench sections 240, second processed via sections 242, and second processed pad sections 244 are formed in the insulating film 204 of the build-up substrate 200, as shown in F7D, the second processed trench sections 240 being sections processed by the pulse laser light having passed through the second trench patterns 332, the second processed via sections 242 being sections processed by the pulse laser light having passed through the second via patterns 334, and the second processed pad sections 244 being sections processed by the pulse laser light having passed through the second pad sections 336 of the second trench patterns 332. The second processed trench sections 240, the second processed via sections 242, and the second processed pad sections 244 are each a recess formed by removal of the insulating film 204 halfway in the depth direction.

The first mask 320 and the second mask 330 are so configured and positioned that the second processed trench sections 240 processed via the second trench patterns 332 are each positioned adjacent to any of the first processed trench sections 230 processed via the multiple first trench patterns 322.

The first mask 320 and the second mask 330 are so configured and positioned that the second via patterns 334 are located within the first pad sections 326 of the first trench patterns 322. Similarly, the first mask 320 and the second mask 330 are so configured and positioned that the first via patterns 324 are located within the second pad sections 336 of the second trench patterns 332.

The first mask 320 and the second mask 330 may instead be so configured and positioned that the first pad sections 326 and the second pad sections 336 are located adjacent to each other. The first mask 320 and the second mask 330 may still instead be so configured and positioned that the first via patterns 324 and the second via patterns 334 are disposed adjacent to each other.

F7E in FIG. 7 shows a cross section of the build-up substrate 200 processed by using the first mask 320 and the second mask 330. Multiple trenches 250, which each correspond to either one of the first processed trench sections 230 or one of the second processed trench sections 240, are processed in the insulating film 204 of the build-up substrate 200, as shown in F7E. The lines and spaces of the multiple trenches 250 are each smaller than or equal to 2 μm.

In addition, pads 252 corresponding to the first processed pad sections 234 are formed in the insulating film 204 of the build-up substrate 200, and vias 254 corresponding to the second processed via sections 242 are formed inside the pads 252. Similarly, pads 256 corresponding to the second processed pad sections 244 are formed in the insulating film 204 of the build-up substrate 200, and vias 258 corresponding to the first processed via sections 232 are formed inside the pads 256.

### 3.2 Operation

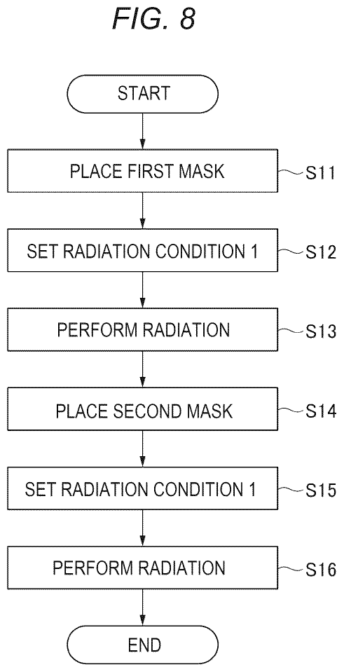

FIG. 8 is a flowchart showing steps of a laser processing method according to the first embodiment. The laser processing method is an example of the “laser processing method for irradiating a workpiece with laser light output from a laser apparatus via a mask” according to the present disclosure.

In step S11, the user places the first mask 320 in the laser processing apparatus 14.

In step S12, the laser processing processor 100 sets the radiation condition to the radiation condition 1. The radiation condition 1 is a condition under which only the portions processed by using both the first mask 320 and the second mask 330 pass through the insulating film 204, and the portions processed by using only one of the first mask 320 and the second mask 330 do not pass through the insulating film 204. Specifically, the radiation condition 1 is a condition under which the second processed via sections 242 pass through the insulating film 204 but the second processed trench sections 240 not to pass through the insulating film 204 after the formation of the pads 252. For example, the laser processing processor 100 sets a condition under which the processed portions pass through the insulating film 204 with the number of pulses being twice the number of pulses in the radiation condition 1.

In step S13, the laser processing apparatus 14 irradiates the surface of the build-up substrate 200 with the pulse laser light via the first mask 320 to perform the processing. The first processed trench sections 230, the first processed via sections 232, and the first processed pad sections 234 are thus formed in the insulating film 204 of the build-up substrate 200.

In step S14, the user places the second mask 330 in the laser processing apparatus 14. The second processed trench sections 240 processed via the second trench patterns 332 of the second mask 330 are positioned so as to be adjacent to the first processed trench sections 230 in the insulating film 204 of the build-up substrate 200. The second processed via sections 242 processed via the second via patterns 334 of the second mask 330 are positioned so as to be located inside the first processed pad sections 234. The second pad sections 336 of the second trench patterns 332 of the second mask 330 are positioned so as to include the first processed via sections 232 in the insulating film 204 of the build-up substrate 200.

In step S15, the laser processing processor 100 sets the radiation condition to the radiation condition 1. Since the radiation condition 1 set in step S15 is the same as the radiation condition 1 set in step S12, the process in step S15 may be omitted.

In step S16, the laser processing apparatus 14 irradiates the surface of the build-up substrate 200 with the pulse laser light via the second mask 330 to perform the processing. The second processed trench sections 240, the second processed via sections 242, and the second processed pad sections 244 are thus further formed in the insulating film 204 of the build-up substrate 200 in which the first processed trench sections 230, the first processed via sections 232, and the first processed pad sections 234 have been formed. As a result, the trenches 250, the pads 252 and 256, and the vias 254 and 258 are formed in the insulating film 204 of the build-up substrate 200. The processes in the flowchart are thus completed.

Thus, the trenches 250 are formed in the insulating film 204 of the build-up substrate 200 at the positions corresponding to the first trench patterns 322 and the second trench patterns 332, the pads 252 and 256 are formed at the positions corresponding to the first pad sections 326 of the first trench patterns 322 and the second pad sections 336 of the second trench patterns 332, respectively, the vias 254 and 258 are formed at the positions corresponding to the first via patterns 324 and the second via patterns 334, respectively.

The processing using the first mask 320 is performed, and the processing using the second mask 330 is then performed in the above description. Instead, the processing using the second mask 330 may be performed, and the processing using the first mask 320 may then be performed.

### 3.3 Effects and Advantages

According to the first embodiment, using a mask having both trench patterns and via patterns mixed with each other allows trenches that do not pass through an insulating film and vias that pass through the insulating film to be processed without an increase in the number of masks.

Furthermore, the first embodiment, in which double patterning is performed, allows suppression of shoulder slopes of the trenches and miniaturization of line and space patterns.

### 3.4 Variation

### 3.4.1 Configuration and Operation

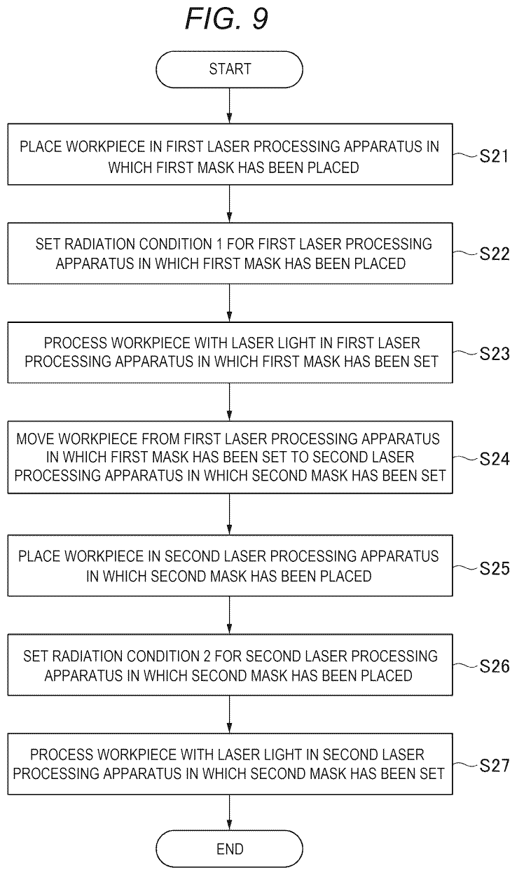

The processing method according to the first embodiment may be carried out by using multiple processing apparatuses. FIG. 9 is a flowchart showing steps of a processing method according to a variation of the first embodiment. The variation will be described below with reference to an example using a first laser processing system and a second laser processing system neither of which is shown. The first laser processing system and the second laser processing system each have the same configuration of the laser processing system 10, and include a first laser processing apparatus and a second laser processing apparatus, respectively. At the start of the flowchart, the first mask 320 is placed in the first laser processing apparatus, and the second mask 330 is placed in the second laser processing apparatus.

In step S21, the user places the build-up substrate 200 as the workpiece 160 in the first laser processing apparatus.

In step S22, the laser processing processor of the first laser processing apparatus sets the radiation condition to the radiation condition 1.

In step S23, the first laser processing apparatus irradiates the surface of the build-up substrate 200 with the pulse laser light via the first mask 320 to perform the processing. The first processed trench sections 230, the first processed via sections 232, and the first processed pad sections 234 are thus formed in the insulating film 204 of the build-up substrate 200.

In step S24, the user moves the build-up substrate 200 from the first laser processing apparatus to the second laser processing apparatus. The build-up substrate 200 may be moved, for example, by a robot that is not shown.

In step S25, the user places the build-up substrate 200 in the second laser processing apparatus.

In step S26, the laser processing processor of the second laser processing apparatus sets the radiation condition to the radiation condition 2. The radiation condition 2 may be the same as the radiation condition 1, but may have parameters different from those of the radiation condition 1. For example, the radiation condition 2 may be so set for the second laser processing apparatus that the second laser processing apparatus can perform the processing to the same depth to which the first laser processing apparatus performs the processing.

In step S27, the second laser processing apparatus irradiates the surface of the build-up substrate 200 with the pulse laser light via the second mask 330 to perform the processing. The second processed trench sections 240, the second processed via sections 242, and the second processed pad sections 244 are thus further formed in the insulating film 204 of the build-up substrate 200 in which the first processed trench sections 230, the first processed via sections 232, and the first processed pad sections 234 have been formed. As a result, the trenches 250, the pads 252 and 256, and the vias 254 and 258 are formed in the insulating film 204 of the build-up substrate 200. The processes in the flowchart are thus completed.

### 3.4.2 Effects and Advantages

The processing method according to the variation of the first embodiment, in which the mask is not switched to another in the processing apparatus, can reduce the number of steps of positioning the mask.

### 4. Second Embodiment

The first embodiment has been described with reference to the case where a portion where patterns of two masks overlap with each other is processed twice under the same radiation condition to form through vias. However, due to variations in the formation of the insulating film and in the processing condition set for the laser processing system and other factors, the processing may be so performed that the number of radiation pulses is small with respect to the thickness of the insulating film. In this case, vias that do not pass through the insulating film may be produced, which may result in a decrease in yield. To avoid the situation described above, a thicker insulating film may be formed in advance, and the number of radiation pulses via each mask may be increased. In other words, reducing the degree of contribution of one pulse to the processing can reduce the influence of the variations on the processing.

### 4.1 Configuration

A build-up substrate 200A according to a second embodiment includes an insulating film 204A having a relatively large thickness formed in advance. The insulating film 204A may, for example, be at least 1.1 times thicker than in the case according not to the second embodiment, and may be at least 1.1 times thicker than that required for an electronic device.

The configuration of the laser processing system 10 is the same as that in the first embodiment. The number of pulses in the radiation condition for the laser processing apparatus 14 is set to be at least 1.1 times the number of pulses required for the processed portion to pass through the insulating film 204A having been formed relatively thick.

### 4.2 Operation

The operation of the laser processing apparatus 14 is basically the same as that in the first embodiment, but the total number of pulses for the two masks is set to be greater than the number of pulses that causes the processed portion to pass through the insulating film.

For example, the insulating film 204A is formed so as to have a thickness of 15 μmt, which is at least 1.1 times thicker than a final thickness of 10 μmt. The term 10 μmt means a thickness or depth of 10 micrometers. When the processing rate is set at 1 μm/pulse, the number of pulses that allows the processed portion to pass through the insulating film 204A is 15 pulses. The number of pulses in the processing using each of the first mask 320 and the second mask 330 placed in the laser processing apparatus 14 is set at 10 pulses (10-μm processing). Therefore, the total number of pulses for the two masks, which is 20 pulses, is at least 1.1 times the number of pulses that allows the processed portion to pass through the insulating film 204A, which is 15 pulses, and the processing depth is 20 μmt, so that the possibility of processed portions that do not pass through the insulating film can be reduced. As described above, 20 pulses in total are radiated to the insulating film 204A having the thickness of 15 μmt to process the insulating film 204A by 20 μm, so that the processed portions can pass through the insulating film 204A.

The extra film portion at the upper surface of the insulating film 204A, which has been formed relatively thick in advance, is removed by CMP (chemical mechanical polishing) after the formation of a wiring layer through plating.

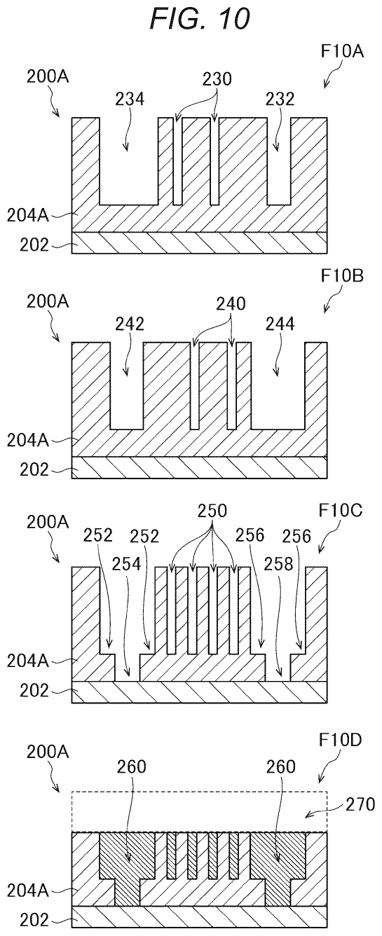

FIG. 10 shows a processing method according to a second embodiment. The build-up substrate 200A shown in FIG. 10 includes the substrate 202 and the insulating film 204A layered on the upper surface of the substrate 202. The insulating film 204A is at least 1.1 times thicker than the insulating film 204 on the build-up substrate 200 in the first embodiment, and is, for example, 15 μmt thick.

F10A in FIG. 10 shows the build-up substrate 200A processed by using the first mask 320. The first processed trench sections 230, the first processed via sections 232, and the first processed pad sections 234 are processed in the insulating film 204A of the build-up substrate 200A shown in F10A. The first processed trench sections 230, the first processed via sections 232, and the first processed pad sections 234 are each processed to the depth of 10 μm in the thickness direction of the insulating film 204A.

F10B in FIG. 10 shows the build-up substrate 200A processed by using the second mask 330. The second processed trench sections 240, the second processed via sections 242, and the second processed pad sections 244 are processed in the insulating film 204A of the build-up substrate 200A shown in F10B. The second processed trench sections 240, the second processed via sections 242, and the second processed pad sections 244 are processed to the depth of 10 μm in the thickness direction of the insulating film 204A.

F10C in FIG. 10 shows a cross section of the build-up substrate 200A processed by using the first mask 320 and the second mask 330. The trenches 250, the pads 252 and 256, and the vias 254 and 258 are processed in the insulating film 204A of the build-up substrate 200A, as shown in F10C. The vias 254 and 258 have received the pulse laser light radiated both during the processing using the first mask 320 and during the processing using the second mask 330, and have therefore received the pulse laser light that can produce vias having the depth of 20 μm. The vias 254 and 258 therefore reliably pass through the insulating film 204A.

F10D in FIG. 10 shows a state in which an excess portion 270 at the upper surface of the insulating film 204A has been removed after wiring layers 260 are formed in the trenches 250, the pads 252 and 256, and the vias 254 and 258. The excess portion 270 is, for example, a portion having a thickness of 5 μm in the film thickness direction from the upper surface of the insulating film 204A. The excess portion 270 is removed to make the thickness of the insulating film 204A equal to that of the insulating film 204 of the build-up substrate 200 in the first embodiment.

### 4.3 Effects and Advantages

The second embodiment, which can prevent the occurrence of blind vias, allows suppression of a decrease in yield.

### 5. Third Embodiment

### 5.1 Configuration

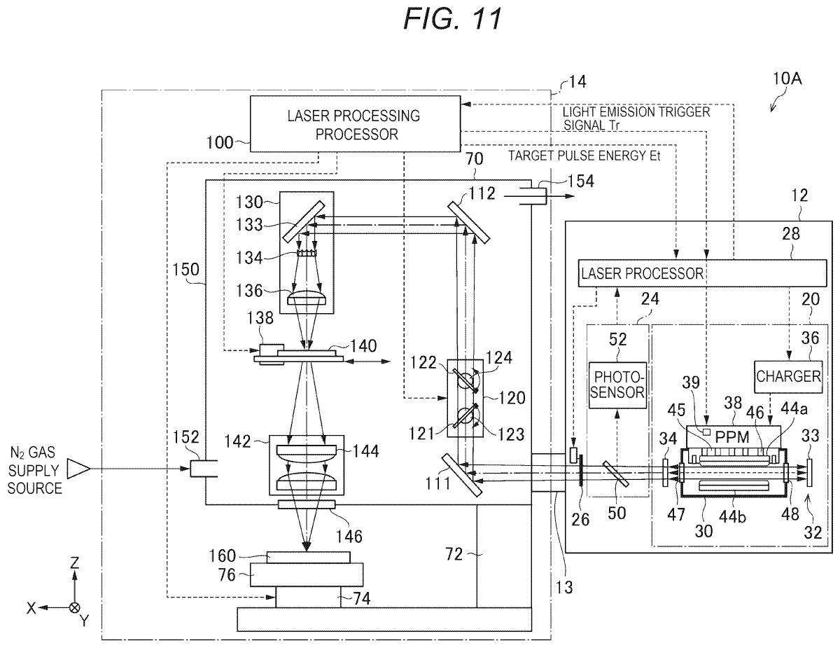

FIG. 11 shows the configuration of a laser processing system 10A according to a third embodiment. The laser apparatus 12 of the laser processing system 10A may be an excimer laser apparatus, a solid-state laser apparatus that outputs ultraviolet pulse laser light, or an apparatus including a solid-state laser apparatus and an excimer amplifier. The same holds true for the laser apparatus 12 according to the first embodiment and the laser apparatus 12 according to the second embodiment.

The laser processing apparatus 14 of the laser processing system 10A includes a mask moving mechanism 138, as shown in FIG. 11. The mask moving mechanism 138 is connected to the laser processing processor 100.

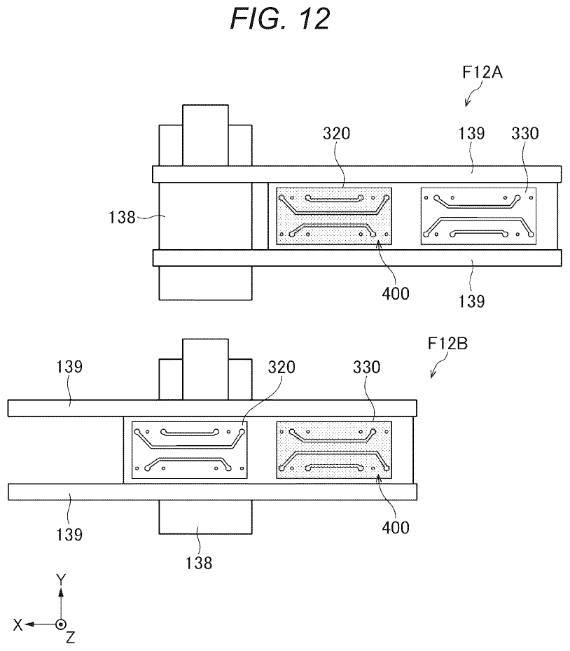

FIG. 12 is a plan view of a mask movement mechanism. The mask moving mechanism 138 includes a frame 139. The frame 139 is a mask placement member at which the first mask 320 and the second mask 330 are placed. The mask moving mechanism 138 can selectively position either the first mask 320 or the second mask 330 in a laser light irradiated region 400 by moving the frame 139. The laser light irradiated region 400 is an example of the “laser light irradiated position” in the present disclosure, and corresponds to the rectangular region of the radiation beam shown in FIG. 2. In the example shown in FIG. 12, the mask moving mechanism 138 is configured to be capable of translating the frame 139, at which the first mask 320 and the second mask 330 are placed, in the X direction and the −X direction in the XY plane.

In place of the example shown in FIG. 12, the mask moving mechanism 138 may be configured to be capable of rotating the first mask 320 and the second mask 330 by rotating a disk which serves as the mask placement member and at which the first mask 320 and the second mask 330 are placed in the XY plane around an axis parallel to the Z direction and selectively position either the first mask 320 or the second mask 330 in the laser light irradiated region 400. The first mask 320 and the second mask 330 may be formed at the same mask substrate.

### 5.2 Operation

The laser processing processor 100 causes the mask moving mechanism 138 to position the first mask 320 in the laser light irradiated region 400 and performs the processing under the radiation condition 1.

The laser processing processor 100 subsequently causes the mask moving mechanism 138 to position the second mask 330 in the laser light irradiated region 400 and performs the processing under the radiation condition 2. The radiation condition 2 may be the same as the radiation condition 1, but may have parameters different from those of the radiation condition 1. For example, the radiation condition 2 may be so set that processing can be performed to the same depth to which the processing using the first mask 320 is performed.

### 5.3 Effects and Advantages

Automatically replacing the first mask 320 with the second mask 330 or vice versa can reduce the number of steps required for mask replacement.

### 6. Electronic Devices Manufacturing Method

After forming trenches, pads, and vias in the workpiece 160 by carrying out the laser processing method according to any of the first to third embodiments, electronic devices can be manufactured by executing multiple steps.

The workpiece 160 may be an interposer substrate that relays a semiconductor integrated circuit to a substrate. An interposer is produced by processing the interposer substrate by carrying out the laser processing method according to any of the first to third embodiments. The interposer and the semiconductor integrated circuit that is not shown are joined and electrically connected to each other. The interposer and a circuit board that is not shown are joined and electrically connected to each other. The procedure described above allows manufacture of an electronic device in which the semiconductor integrated circuit and the circuit board are electrically connected to each other via the interposer.

### 7. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, the term “at least one of A, B, and C” should be interpreted to mean any of A, B, C, A+B, A+C, B+C, and A+B+C. Moreover, the term described above should be interpreted to include combinations of any thereof and any other than A, B, and C.

What is claimed is:

1. A laser processing method for irradiating a workpiece with laser light output by a laser apparatus via a mask,
the workpiece including a substrate and an insulating film formed on the substrate,
the irradiation via the mask including
irradiating the workpiece with the laser light via a first mask pattern in which a first via pattern and a first trench pattern including a first pad section are formed, and
irradiating the workpiece with the laser light via a second mask pattern in which a second trench pattern and a second via pattern are formed,
irradiating the workpiece with the laser light via the second mask pattern including
positioning a second processed trench section processed via the second trench pattern so as to be adjacent to a first processed trench section of the workpiece processed via the first trench pattern, and
positioning a second processed via section processed via the second via pattern so as to be inside a first processed pad section of the workpiece processed via the first pad section.

2. The laser processing method according to claim 1,
further comprising setting a radiation condition for the laser apparatus,
wherein the radiation condition under which the laser light is radiated via the first mask pattern is the same as the radiation condition under which the laser light is radiated via the second mask pattern.

3. The laser processing method according to claim 2,
wherein the radiation condition includes at least one of a fluence, a pulse count, and a repetition frequency of the laser light.

4. The laser processing method according to claim 3,
wherein the radiation condition is a condition that causes the second processed via section to pass through the insulating film but is a condition that causes the second processed trench section not to pass through the insulating film in the laser light radiation via the second mask pattern.

5. The laser processing method according to claim 1,
wherein the second trench pattern of the second mask pattern includes a second pad section, and
a second processed pad section processed via the second pad section is positioned so as to include a first processed via section of the workpiece processed via the first via pattern.

6. The laser processing method according to claim 5,
wherein the second processed pad section is positioned at a position where the second processed pad section is adjacent to the first processed pad section, and
the second processed via section is positioned at a position where the second processed via section is adjacent to the first processed via section.

7. The laser processing method according to claim 1,
wherein the laser light is excimer laser light.

8. The laser processing method according to claim 2,
wherein the insulating film is formed to have a thickness at least greater than 1.1 times a necessary thickness, and
the radiation condition includes a pulse count greater than at least 1.1 times a pulse count that allows a processed portion to pass through the insulating film.

9. The laser processing method according to claim 8,
further comprising removing the insulating film by using CMP.

10. The laser processing method according to claim 9,
further comprising forming a wiring layer by using plating at processed portions of the workpiece processed via the first and second mask patterns before the removal of the insulating film using CMP.

11. The laser processing method according to claim 1,
wherein irradiating the workpiece with the laser light via the first mask pattern is performed in a first laser processing apparatus, and
irradiating the workpiece with the laser light via the second mask pattern is performed in a second laser processing apparatus different from the first laser processing apparatus.

12. The laser processing method according to claim 11,
further comprising moving the workpiece from the first laser processing apparatus to the second laser processing apparatus with the aid of a robot.

13. The laser processing method according to claim 1,
wherein lines and spaces of multiple trenches where the first processed trench section and the second processed trench section are adjacent to each other each have a dimension of 2 μm or smaller.

14. An electronic device manufacturing method for manufacturing an electronic device by irradiating a workpiece with laser light output by a laser apparatus via a mask,
the workpiece including a substrate and an insulating film formed on the substrate,
the irradiation via the mask including
irradiating the workpiece with the laser light via a first mask pattern in which a first via pattern and a first trench pattern including a first pad section are formed, and
irradiating the workpiece with the laser light via a second mask pattern in which a second trench pattern and a second via pattern are formed,
irradiating the workpiece with the laser light via the second mask pattern including
positioning a second processed trench section processed via the second trench pattern so as to be adjacent to a first processed trench section of the workpiece processed via the first trench pattern, and
positioning a second processed via section processed via the second via pattern so as to be inside a first processed pad section of the workpiece processed via the first pad section.

15. The electronic device manufacturing method according to claim 14,
wherein the workpiece is an interposer substrate, and
the method further comprises:
producing an interposer by irradiating the interposer substrate with the laser light to process the interposer substrate;
bonding the interposer to a semiconductor integrated circuit to electrically connect the interposer to the semiconductor integrated circuit; and
bonding the interposer to a circuit board to electrically connect the interposer to the circuit board.

16. A laser processing apparatus for irradiating a workpiece with laser light output by a laser apparatus via a mask, the laser processing apparatus comprising:
a mask placement member at which a first mask and a second mask are placed;
a mask moving mechanism configured to move one of the first mask and the second mask placed at the mask moving member to a position where the laser light is radiated; and
a processor,
the processor
moving the first mask to the position where the laser light is radiated, and irradiating the workpiece with the laser light via a first via pattern and a first trench pattern including a first pad section, the first via pattern and the first trench pattern formed at the first mask, and
moving the second mask to the position where the laser light is radiated, and irradiating the workpiece with the laser light via a second trench pattern and a second via pattern formed at the second mask,
irradiating the workpiece with the laser light via the second trench pattern and the second via pattern including
positioning a second processed trench section processed via the second trench pattern so as to be adjacent to a first processed trench section of the workpiece processed via the first trench pattern, and
positioning a second processed via section processed via the second via pattern so as to be inside a first processed pad section of the workpiece processed via the first pad section.

17. The laser processing apparatus according to claim 16,
wherein the mask moving mechanism is configured to translate or rotate the first mask and the second mask placed at the mask placement member.

18. The laser processing apparatus according to claim 17,
wherein the first mask and the second mask are formed at a single mask substrate.
